(19) United States
(12) Patent Application Publication
(10) Pub. No.: US 2026/0354115 A1
(43) Pub. Date: Nov. 5, 2026

(54) FILM FRAME CARRIER CHUCK TO SECURE EXTREME WARP WAFERS

(71) Applicant: KLA Corporation, Milpitas, CA (US)

(72) Inventors: Harit Maganlal Gadhia, Singapore (SG); Mathankumar Thangaraj, Singapore (SG); Chow Tian Lim, Singapore (SG); Sven Schwitalla, Marburg (DE)

(21) Appl. No.: 19/332,876

(22) Filed: Sep. 18, 2025

Related U.S. Application Data
(60) Provisional application No. 63/799,591, filed on May 4, 2025.

(51) Int. Cl. H10P 72/78; H04N 23/56

(52) U.S. Cl. CPC H10P 72/78; H04N 23/56

(57) ABSTRACT

A chuck is disclosed. The chuck may include an upper body opposing the lower body and including a plurality of vacuum holes and a groove. The chuck may include a seal disposed in the groove of the upper body and extending upward from the upper body. The chuck may include a rim disposed between the lower body and the upper body and extending inwards from a perimeter of the lower body and a perimeter of the upper body. The chuck may include a plurality of ribs disposed between the lower body and the upper body and within the rim, wherein ribs within the plurality of ribs intersect one another to define a plurality of pockets.

### CROSS-REFERENCE TO RELATED APPLICATION

The present application claims the benefit under 35 U.S.C. § 119(e) of U.S. Provisional Application Serial Number 63/799,591, filed May 4, 2025, entitled FILM FRAME CARRIER CHUCK TO SECURE EXTREME WARP WAFERS, which is incorporated herein by reference in the entirety.

### TECHNICAL FIELD

The present disclosure relates generally to chucks and, more particularly, to chucks designed to hold extremely warped wafers.

### BACKGROUND

When inspecting wafers, the wafers may be disposed on a chuck. However, chucks are generally not designed to accommodate highly warped wafers. Current chuck designs may only accommodate wafers with warpages of up to 200 micrometers. Therefore, wafers with warpages greater than 200 micrometers may not be able to be affixed to a chuck in order to be inspected. Accordingly, it is desirable to develop systems and methods to address these limitations.

### SUMMARY

A chuck is disclosed, in accordance with one or more embodiments of the present disclosure. In embodiments, the chuck includes a lower body. In embodiments, the chuck includes an upper body opposing the lower body and including a plurality of vacuum holes and a groove. In embodiments, the chuck includes a seal disposed in the groove of the upper body and extending upward from the upper body. In embodiments, the chuck includes a rim disposed between the lower body and the upper body and extending inwards from a perimeter of the lower body and a perimeter of the upper body. In embodiments, the chuck includes a plurality of ribs disposed between the lower body and the upper body and within the rim, wherein ribs within the plurality of ribs intersect one another to define a plurality of pockets.

A characterization system is disclosed, in accordance with one or more embodiments of the present disclosure. In embodiments, the characterization system includes an imaging sub-system to inspect a wafer disposed on a chuck with illumination. In embodiments, the chuck includes a lower body. In embodiments, the chuck includes an upper body opposing the lower body and including a plurality of vacuum holes and a groove. In embodiments, the chuck includes a seal disposed in the groove of the upper body and extending upward from the upper body. In embodiments, the chuck includes a rim disposed between the lower body and the upper body and extending inwards from a perimeter of the lower body and a perimeter of the upper body. In embodiments, the chuck includes a plurality of ribs disposed between the lower body and the upper body and within the rim, wherein ribs within the plurality of ribs intersect one another to define a plurality of pockets.

A method is disclosed, in accordance with one or more embodiments of the present disclosure. In embodiments, the method includes a step of bonding a wafer to a chuck with an air source that creates a vacuum between the wafer and the chuck. In embodiments, the chuck includes a lower body. In embodiments, the chuck includes an upper body opposing the lower body and including a plurality of vacuum holes and a groove. In embodiments, the chuck includes a seal disposed in the groove of the upper body and extending upward from the upper body. In embodiments, the chuck includes a rim disposed between the lower body and the upper body and extending inwards from a perimeter of the lower body and a perimeter of the upper body. In embodiments, the chuck includes a plurality of ribs disposed between the lower body and the upper body and within the rim, wherein ribs within the plurality of ribs intersect one another to define a plurality of pockets. In embodiments, the method includes a step of inspecting the wafer with a characterization system. In embodiments, the method includes a step of debonding the wafer with a clean dry air purge generated by the air source.

### BRIEF DESCRIPTION OF THE DRAWINGS

The numerous advantages of the disclosure may be better understood by those skilled in the art by reference to the accompanying figures.

FIG. 1A illustrates an exploded perspective view of a chuck, in accordance with one or more embodiments of the present disclosure.

FIG. 1B illustrates a top perspective view of the chuck, in accordance with one or more embodiments of the present disclosure.

FIG. 2 illustrates a cross-sectional view of the chuck with a wafer, in accordance with one or more embodiments of the present disclosure.

FIG. 3 illustrates a block diagram of a characterization system, in accordance with one or more embodiments of the present disclosure.

FIG. 4 illustrates a flow diagram of a method, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a chuck designed to hold wafers. These wafers may include highly warped wafers. In order to accommodate wafers with large warpages, the chuck may include a seal around the perimeter of the chuck. The seal may be situated in a groove and extend upwards from the top surface of the chuck. The seal may contact the wafer such that the entire seal is in contact with the wafer. The contact between the seal and the wafer may form a vacuum between the wafer and the surface of the chuck. The vacuum may hold the wafer in place on the chuck, despite the wafer being highly warped.

An air source capable of blowing and/or drawing air may generate the vacuum between the wafer and the chuck. Because of the high warpage of the wafers, an air source with a high volumetric flow rate (e.g., above 55 liters per minute) may generate the vacuum. Additionally, after inspection of the wafer, the air source may initiate a clean dry air (CDA) purge in order to assist in unbonding the wafer from the chuck.

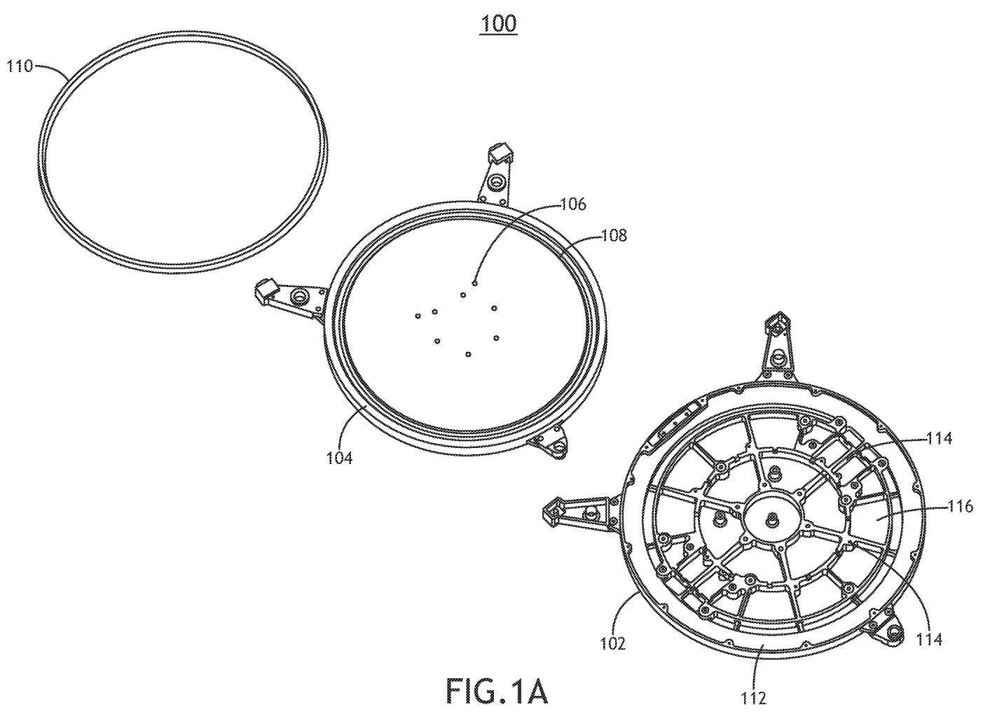

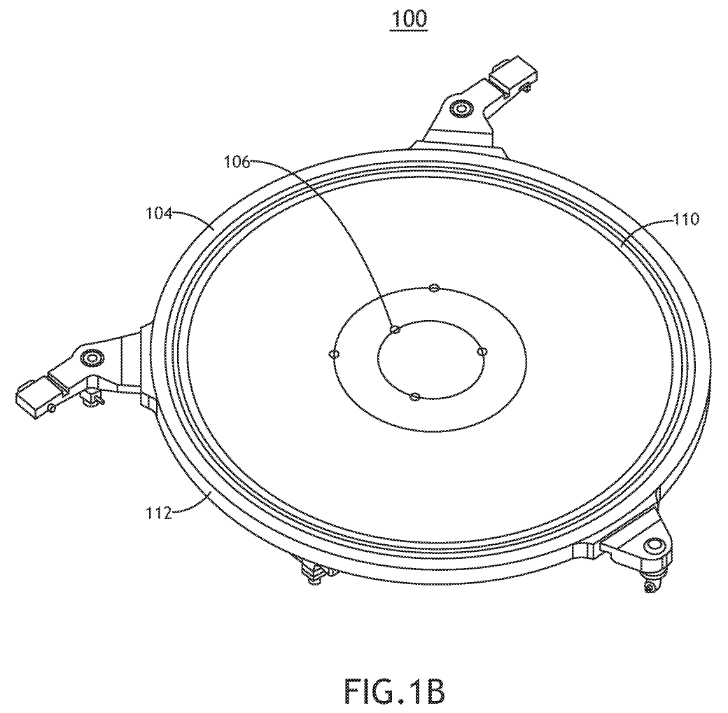

FIG. 1A illustrates an exploded perspective view of a chuck 100, in accordance with one or more embodiments of the present disclosure. FIG. 1B illustrates a top perspective view of the chuck 100, in accordance with one or more embodiments of the present disclosure.

In embodiments, the chuck 100 includes a lower body 102 and an upper body 104. The lower body 102 and the upper body 104 may oppose each other. The lower body 102 and the upper body 104 may be circular and have the same size. It is contemplated that both the lower body 102 and the upper body 104 may have radii of 12 inches or more.

In embodiments, the upper body 104 includes multiple vacuum holes 106. The vacuum holes 106 may be a collection of small holes through the upper body 104 in order to allow air to flow through the upper body 104.

In embodiments, the upper body 104 includes a groove 108. The groove may be an indentation about the perimeter of the upper body 104. The groove 108 may encircle the entirety of the vacuum holes 106.

In embodiments, the chuck 100 includes a seal 110. The seal 110 may be disposed within the groove 108. The groove 108 may have a depth that allows a portion of the seal 110 to sit within the groove 108, while the rest of the seal 110 extends above the groove 108 and the surface of the upper body 104. The groove 108 may secure the seal 110 to prevent motion of the seal 110 during operation of the chuck 100. For example, an adhesive may secure the seal 110 within the groove 108. By way of another example, a press-fit clearance may secure the seal 110 in the groove 108 (e.g., the seal 110 is press-fit into the groove 108). The seal 110 may use any material capable of having constant contact with a wafer. For example, the seal 110 may be a rubber seal.

In embodiments, the chuck 100 includes a rim 112 disposed between the lower body 102 and the upper body 104. The rim 112 may begin at the perimeter of the lower body 102 and the upper body 104 and extend radially inwards. The rim 112 may have a sufficient thickness in order to enhance structural integrity of the chuck 100.

In embodiments, the chuck 100 includes multiple ribs 114. The ribs 114 may sit between the lower body 102 and the upper body 104. The ribs 114 may intersect each other in order to define multiple pockets 116 in the space between the lower body 102 and the upper body 104. The ribs 114 may have any combination of shapes and/or contours. For example, the ribs 114 may include any combination of rounded (or circular) ribs 114 and/or straight ribs 114.

It is contemplated that the ribs 114 and the rim 112 may have a height such that both the ribs 114 and the rim 112 are in contact with both the lower body 102 and the upper body 104. Additionally, the rim 112 may entirely encircle the ribs 114.

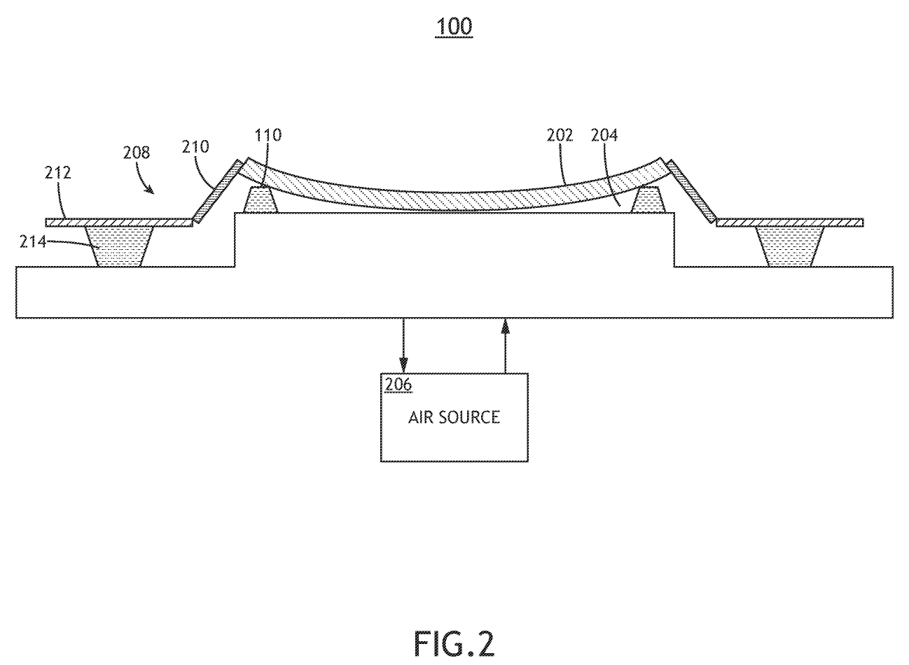

FIG. 2 illustrates a cross-sectional view of the chuck 100 with a wafer 202, in accordance with one or more embodiments of the present disclosure. For example, the chuck 100 may secure the wafer 202 in order to inspect the wafer 202. It is noted that the wafer 202 may include any wafer known in the art such as a semiconductor or non-semiconductor wafer

In embodiments, the chuck 100 is configured to secure the wafer 202. For example, the seal 110 may accept the wafer 202. The chuck 100 may accommodate wafers 202 with extreme warpages. For example, the seal may accept wafers 202 with warpages of at least 4 millimeters. The seal 110 and the wafer 202 may form a cavity 204. The cavity 204 may be an area between the bottom of the wafer 202 and the top of the upper body 104.

In embodiments, the chuck 100 includes an air source 206. The air source 206 may include any device capable of blowing air and/or drawing air. Blowing air may into the cavity 204 cause the wafer 202 to debond from the seal 110 of the chuck 100, while drawing air from the cavity 204 may cause the wafer 202 to bond to the seal 110 of the chuck 100. For example, the air source 206 may draw air from the cavity 204 in order to form a vacuum within the cavity 204. In this way, the air source 206 may remove air in order to form the cavity 204 between the wafer 202 and the upper body 104 (e.g., the air source 206 may remove air by the vacuum holes 106 of the upper surface).

Due to the high warpage of the wafer 202, it may be desirable to use an air source 206 with a high volumetric flow rate. For example, the air source 206 may have a volumetric flow rate of at least fifty-five liters per minute (LPM). However, this should be interpreted as illustrative rather than limiting, as the air source 206 may have any volumetric flow rate capable of securing the wafer 202 to the chuck 100.

After inspection of the wafer 202, the wafer 202 and the chuck 100 may debond from each other. However, after the air source 206 stops drawing air from the cavity 204, a vacuum may still exist within the cavity 204. The presence of a vacuum within the cavity may keep the wafer 202 secured to the chuck. Therefore, the air source 206 may switch from drawing air from the cavity 204 to blowing air into the cavity 204 to debond the wafer 202 from the chuck 100. For example, the air source 206 may use a clean dry air purge to debond the wafer 202 from the chuck 100. The clean dry air purge may also reduce bouncing and vibration of the wafer 202 as the wafer 202 is removed from the chuck 100.

In embodiments, the wafer 202 is coupled to, or mounted on, a film frame carrier 208. The film frame carrier may include a film 210 and a frame 212. For example, the film 210 may couple the wafer 202 to the film frame carrier 208. The frame 212 may be a rigid surface about the perimeter of the film frame carrier 208. The film 210 may couple to the wafer 202 at, or near, the perimeter of the wafer 202.

In embodiments, the chuck 100 includes one or more suction cups 214 spaced about the perimeter of the chuck 100 (e.g., radially outwards from the lower body 102 and the upper body 104). The suction cups 214 may bond to the frame 212 of the film frame carrier 208 and pull the frame downward. In this way, the suction cups 214 may further secure the wafer to the chuck 100 (e.g., due to increased pressure on the wafer 202 against the seal 110). The one or more suction cups 214 may facilitate film frame carrier 208 handling during characterization of the wafer 202.

It is contemplated that the chuck 100 may help flatten the wafer 202. For example, the wafer 202 being vacuumed against the seal 110 may aid in flattening the wafer 202. Additionally, the interaction between the suction cups 214 and the film frame carrier 208 may pull the wafer 202 down against the seal 110, helping to further flatten the wafer 202. After the wafer 202 is flattened against the chuck 100, the seal 110 may collapse inside the groove 108, resulting in a flat surface for the wafer 202 to rest against. It is noted that the seal 110 may be made from a material selected to prevent deformation of the wafer 202.

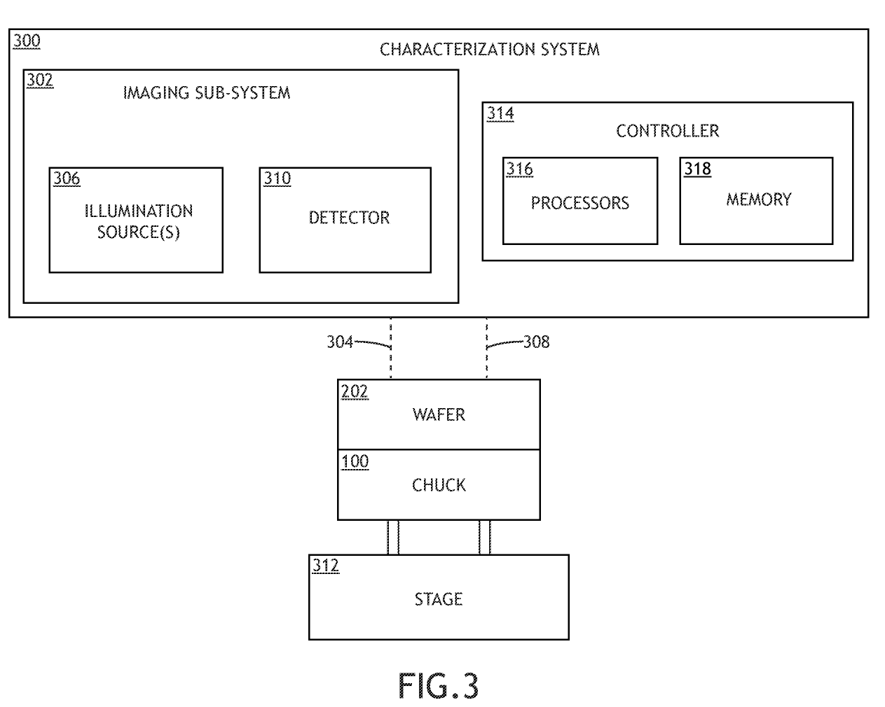

FIG. 3 illustrates a block diagram of a characterization system 300, in accordance with one or more embodiments of the present disclosure. The characterization system 300 may include the chuck 100. The characterization system 300 may be an inspection system or a metrology system.

In embodiments, the characterization system 300 may inspect the wafer 202 with an imaging sub-system 302. The imaging sub-system 302 may generate one or more images of the wafer 202 for inspection and/or imaging-based metrology of the wafer 202. For example, the imaging sub-system 302 may illuminate the wafer 202 with illumination 304 from one or more illumination sources 306 and generate an image of the wafer 202 in response to light from the wafer 202 (e.g., sample light 308) using a detector 310. Additionally, the characterization system 300 may include a stage 312 coupled to, and configured to move, the chuck 100. In additional and/or alternative embodiments, the characterization system 300 may configured as a non-imaging based characterization system such as, but not limited to, an ellipsometer, reflectometer, or scatterometer metrology system or other measurement system.

In embodiments, the characterization system 300 includes a controller 314. The controller 314 may include one or more processors 316 configured to execute program instructions maintained on a memory 318. The imaging sub-system 302 may be communicatively coupled to the controller 314. In this regard, the controller 314 may receive images from the detector 310 and generate one or more measurements of the wafer based on the images received from the detector 310. Additionally, it is contemplated that the controller 314 may control the air source 206. For example, the controller 314 may cause the air source 206 to draw air from the cavity 204 to bond the wafer 202 to the chuck 100. By way of another example, the controller 314 may cause the air source 206 to blow air into the cavity 204 to debond the wafer 202 from the chuck 100.

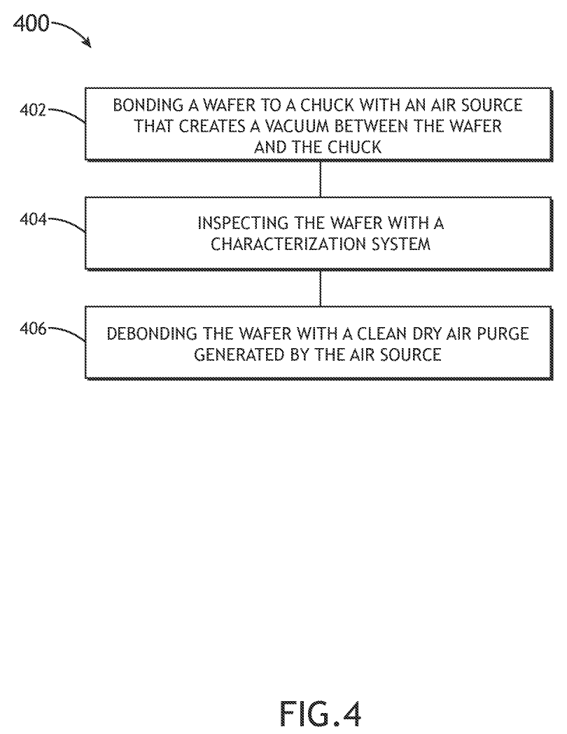

FIG. 4 illustrates a flow diagram of a method 400, in accordance with one or more embodiments of the present disclosure. The embodiments and the enabling technologies described previously herein in the context of the chuck 100 should be interpreted to extend to the method 400. It is further noted, however, that the method 400 is not limited to the architecture of the chuck 100.

In embodiments, the method 400 includes a step 402 of bonding a wafer to a chuck. A vacuum formed between the wafer and a seal of the chuck (e.g., a vacuum formed in a cavity) may bond the wafer to the chuck. An air source capable of blowing air and/or drawing air may generate the vacuum. The seal may protrude upwards from the surface of the chuck to contact an extremely warped wafer (e.g., the seal contacts the wafer around the entire perimeter of the seal). Such a seal and chuck may bond with wafers that would otherwise not be able to be chucked due to their warpage.

In embodiments, the method 400 includes a step 404 of inspecting the wafer with a characterization system. The characterization system may inspect the wafer to generate one or more measurements (e.g., metrology measurements) for the wafer. For example, the characterization system may inspect the wafer to determine if the wafer has one or more defects. It is contemplated that any characterization system suitable for generating measurements of a wafer may inspect the wafer. In this way, the characterization system may be a metrology system or an inspection system.

In embodiments, the method 400 includes a step 406 of debonding the wafer from the chuck. After the wafer is inspected, the wafer may be debonded from the chuck. A clean dry air purge generated by the air source may debond the wafer from the chuck. The air source may generate the clean dry air purge after the air source has stopped drawing air from a cavity between the wafer and the chuck (e.g., after the air source stops creating a vacuum between the wafer and the chuck). The clean dry air purge may facilitate removal of the wafer from the chuck with reduced bouncing and vibration effects during unloading.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively "associated" such that the desired functionality is achieved. Hence, any two components herein combined to achieve a particular functionality can be seen as "associated with" each other such that the desired functionality is achieved, irrespective of architectures or intermedial components. Likewise, any two components so associated can also be viewed as being "connected," or "coupled," to each other to achieve the desired functionality, and any two components capable of being so associated can also be viewed as being "couplable," to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases "at least one" and "one or more" to introduce claim recitations. However, the use of such phrases should not be construed to imply that the introduction of a claim recitation by the indefinite articles "a" or "an" limits any particular claim containing such introduced claim recitation to inventions containing only one such recitation, even when the same claim includes the introductory phrases "one or more" or "at least one" and indefinite articles such as "a" or "an" (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of "two recitations," without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed is:

1. A chuck comprising:
a lower body;
an upper body opposing the lower body, wherein the upper body includes:
a plurality of vacuum holes; and
a groove;
a seal disposed in the groove of the upper body and extending upward from the upper body;
a rim disposed between the lower body and the upper body and extending inwards from a perimeter of the lower body and a perimeter of the upper body; and
a plurality of ribs disposed between the lower body and the upper body and within the rim, wherein ribs within the plurality of ribs intersect one another to define a plurality of pockets.

2. The chuck of claim 1, wherein the seal is press-fit into the groove.

3. The chuck of claim 1, wherein the seal is secured in the groove by an adhesive.

4. The chuck of claim 1, wherein the seal accepts a wafer to form a cavity between the wafer and the upper body.

5. The chuck of claim 4, wherein the seal is configured to accommodate a wafer with a warpage of at least 4 millimeters.

6. The chuck of claim 4, further comprising:
an air source configured to blow air into the cavity to debond a wafer from the seal and draw air from the cavity to form a vacuum to bond the wafer to the seal.

7. The chuck of claim 6, wherein the air source debonds the wafer from the seal with a clean dry air purge.

8. The chuck of claim 4, wherein the wafer is mounted on a film frame carrier, wherein the film frame carrier comprises:
a film coupled to the wafer; and
a frame coupled to the film, wherein the frame is a rigid body about the perimeter of the wafer.

9. The chuck of claim 8, further comprising:
one or more suction cups, wherein the one or more suction cups bond to the frame of the film frame carrier.

10. The chuck of claim 9, wherein the one or more suction cups facilitate film frame carrier handling during characterization of the wafer.

11. A characterization system comprising:
an imaging sub-system to inspect a wafer disposed on a chuck with illumination, wherein the chuck comprises:
a lower body;
an upper body opposing the lower body, wherein the upper body includes:
a plurality of vacuum holes; and
a groove;
a seal disposed in the groove of the upper body and extending upward from the upper body;
a rim disposed between the lower body and the upper body and extending inwards from a perimeter of the lower body and a perimeter of the upper body; and
a plurality of ribs disposed between the lower body and the upper body and within the rim, wherein ribs within the plurality of ribs intersect one another to define a plurality of pockets.

12. The characterization system of claim 11, wherein the seal is press-fit into the groove.

13. The characterization system of claim 11, wherein the seal is secured in the groove by an adhesive.

14. The characterization system of claim 11, wherein the seal accepts the wafer to form a cavity between the wafer and the upper body.

15. The characterization system of claim 14, wherein the seal is configured to accommodate the wafer with a warpage of at least 4 millimeters.

16. The characterization system of claim 14, further comprising:
an air source configured to blow air into the cavity to debond a wafer from the seal and draw air from the cavity to form a vacuum to bond the wafer to the seal.

17. The characterization system of claim 16, wherein the air source debonds the wafer from the seal with a clean dry air purge.

18. The characterization system of claim 14, wherein the wafer is mounted on a film frame carrier, wherein the film frame carrier comprises:
a film coupled to the wafer; and
a frame coupled to the film, wherein the frame is a rigid body about the perimeter of the wafer.

19. The characterization system of claim 18, further comprising:
one or more suction cups, wherein the one or more suction cups bond to the frame of the film frame carrier.

20. The characterization system of claim 19, wherein the one or more suction cups facilitate film frame carrier handling during characterization of the wafer.

21. A method comprising:
bonding a wafer to a chuck with an air source that creates a vacuum between the wafer and the chuck, wherein the chuck comprises:
a lower body;
an upper body opposing the lower body, wherein the upper body includes:
a plurality of vacuum holes; and
a groove;
a seal disposed in the groove of the upper body and extending upward from the upper body;
a rim disposed between the lower body and the upper body and extending inwards from a perimeter of the lower body and a perimeter of the upper body; and
a plurality of ribs disposed between the lower body and the upper body and within the rim, wherein ribs within the plurality of ribs intersect one another to define a plurality of vacuum pockets;
inspecting the wafer with a characterization system; and
debonding the wafer with a clean dry air purge generated by the air source.
